(19) United States
(12) Patent Application Publication
(10) Pub. No.: US 2017/0141697 A1
(43) Pub. Date: May 18, 2017

(54) CONTROL BOARD FOR POWER CONVERSION DEVICE

(71) Applicant: AISIN AW CO., LTD., Anjo-shi, Aichi-ken (JP)

(72) Inventors: Shinsuke TSUBAMOTO, Hekinan (JP); Keita MUTSUURA, Miyoshi (JP)

(73) Assignee: AISIN AW CO., LTD., Anjo-shi, Aichi-ken (JP)

(21) Appl. No.: 15/322,961

(22) PCT Filed: Jul. 8, 2015
(86) PCT No.: PCT/JP2015/069682

§ 371 Date: Dec. 29, 2016

(30) Foreign Application Priority Data
Jul. 31, 2014 (JP) 2014-156768

(51) Int. Cl. H02M 7/44; H05K 1/02; H02M 1/14

(52) U.S. Cl. CPC H02M 7/44; H02M 1/14; H05K 1/0204; H05K 2201/06

(57) ABSTRACT

A control board for a power conversion device, the control board including a board body that is a multilayer board; a first circuit mounted on a first surface of the board body and including a heat generator; a second circuit mounted on the first surface of the board body, the second circuit using a voltage different from a voltage of the first circuit; an insulation region formed on the first surface of the board body, the insulation region performing insulation between the first circuit and the second circuit; and a pattern of a thermal conductive material formed on an internal layer of the board body, extending in a region overlapping with the insulation region as seen from a direction orthogonal to the first surface of the board body, and thermally connected to the heat generator.

### BACKGROUND

The present disclosure relates to a control board for a power conversion device.

There is a known electronic device that includes a resistor circuit having three or more resistors connected in series and discharging the electric charge stored in a smoothing capacitor and the resistances of the resistors disposed at both ends are larger than the resistances of the other resistors (see JP-A-2012-039715, for example).

### SUMMARY

However, the electronic device described in JP-A-2012-039715 has a heat radiation pattern for the resistor circuit on the surface of the board, so the component mounting range on the surface of the board is restricted by the heat radiation pattern.

An exemplary aspect of the present disclosure provides a control board for a power conversion device that can achieve a heat radiation function in an aspect in which a restriction on the component mounting range is small.

According to an exemplary aspect of the invention, there is provided a control board for a power conversion device, the control board including a board body that is a multilayer board; a first circuit mounted on a first surface of the board body and including a heat generator; a second circuit mounted on the first surface of the board body, the second circuit using a voltage different from a voltage of the first circuit; an insulation region formed on the first surface of the board body, the insulation region performing insulation between the first circuit and the second circuit; and a pattern of a thermal conductive material formed on an internal layer of the board body, extending in a region overlapping with the insulation region as seen from a direction orthogonal to the first surface of the board body, and thermally connected to the heat generator.

According to the disclosure, it is possible to obtain a control board for a power conversion device that can achieve a heat radiation function in an aspect in which a restriction on the component mounting range is small.

### BRIEF DESCRIPTION OF THE DRAWINGS

Embodiments will be described below with reference to the drawings.

FIG. 1 illustrates an example of an electric circuit including an inverter.

FIG. 2 schematically illustrates a control board for the inverter in the example.

FIG. 3 schematically illustrates a control board for the inverter in another example.

### DETAILED DESCRIPTION OF EMBODIMENTS

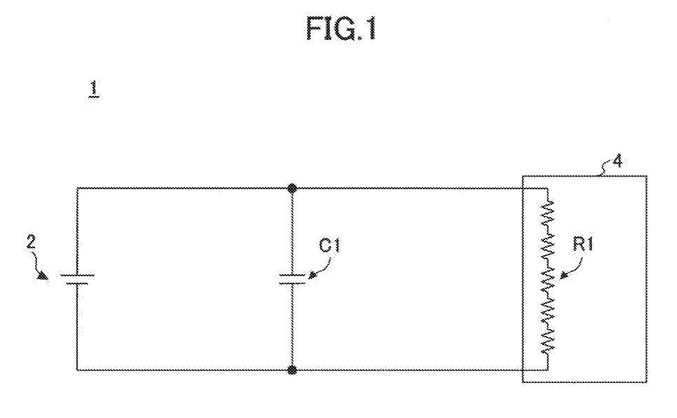

FIG. 1 illustrates an example of the electric circuit 1 including the inverter 4. The electric circuit 1 is used to, for example, drive a motor.

The electric circuit 1 includes a battery 2, the inverter (an example of the power conversion device) 4, a smoothing capacitor C1, and a discharge resistor R1. A motor (not illustrated) is connected to the inverter 4. The motor may be a travelling motor used in a hybrid vehicle or electric vehicle.

The smoothing capacitor C1 is connected between the positive electrode side and the negative electrode side of the battery 2.

The discharge resistor R1 is connected between the positive electrode side and the negative electrode side of the battery 2 in parallel to the smoothing capacitor C1. In the example illustrated in FIG. 1, the plurality of the discharge resistors R1 are connected in series and the plurality of the discharge resistors R1 in series are connected in parallel to the smoothing capacitor C1. The discharge resistor R1 has a function of dissipating (discharging) the electric charge of the smoothing capacitor C1 to the ground. Such discharging may be constantly performed during operation of the inverter 4 or may be performed when (when the inverter 4 stops operating) a relay (not illustrated) is turned off. During the discharging, the discharge resistor R1 generates heat.

In the example illustrated in FIG. 1, a DC-DC converter (another example of the power conversion device) may be provided between the smoothing capacitor C1 and the battery 2.

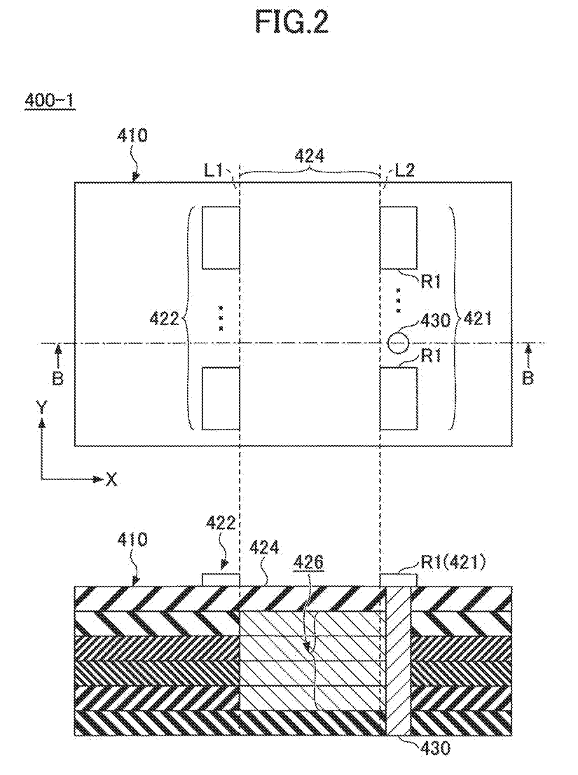

FIG. 2 schematically illustrates the control board 400-1 for the inverter 4 in the example, the upper part of FIG. 2 illustrates illustrates plan view, and the lower part of FIG. 2 is a cross sectional view taken along line B-B in the upper part of FIG. 2. Plan view indicates an aspect of view of the surface of a board body 410 in the vertical direction (the direction orthogonal to the surface). In the following descriptions, for convenience, as illustrated in the upper part of FIG. 2, X and Y directions are defined based on the rectangular outside shape of the board body 410 and the upper side in the lower part of FIG. 2 is defined as the upward direction. However, the orientation of the control board 400-1 for the inverter 4 depends on the mount state of the control board 400-1 for the inverter 4 and the upward direction does not necessarily correspond to the vertically upward direction.

The control board 400-1 includes the board body 410, a first circuit portion 421 (first circuit), a second circuit portion 422 (second circuit), an insulation region 424, and a pattern 426.

The board body 410 is a multilayer board. The board body 410 preferably has two or more internal layers. In the example illustrated in FIG. 2, the board body 410 has four internal layers.

The first circuit portion 421 includes the discharge resistors R1 (an example of the heat generating component/heat generator) mounted on the upper surface (an example of the first surface) of the board body 410. In the example illustrated in FIG. 2, the plurality of discharge resistors R1 are arranged in a single row in the Y direction. However, the plurality of discharge resistors R1 may be arranged in a plurality of rows in the Y direction.

The second circuit portion 422 is mounted on the upper surface of the board body 410. The voltage of the second circuit portion 422 is different from the voltage of the first circuit portion 421. “The difference in the voltage” means use of a different operating voltage and typically mea use of a different power voltage. The difference in the voltage between the second circuit portion 422 and the first circuit portion 421 is, for example, tens of volts or more and typically 100 volts or more. For example, the second circuit portion 422 includes a circuit portion forming a microcomputer controlling the inverter 4. In this case, the first circuit portion 421 forms a high voltage circuit corresponding to the voltage of the electric circuit 1 and the second circuit portion 422 forms a low voltage circuit. In the example illustrated in FIG. 2, the rectangles schematically illustrating the second circuit portion 422 represent resistors.

The insulation region 424 is formed on the upper surface of the hoard body 410. The insulation region 424 performs insulation between the first circuit portion 421 and the second circuit portion 422. The insulation region 424 has 110 conductor portion and may have no electronic components. The insulation region 424 may be made of a material having a CTI (Comparative Tracking Index) higher than the material of the board body 410. The insulation region 424 is formed between the first circuit portion 421 and the second circuit portion 422 so as to obtain the minimum creepage distance defined by a standard such as, for example, JIS. The insulation region 424 is preferably formed adjacently to the first circuit portion 421. In the example illustrated in FIG. 2, the insulation region 424 is formed in the X direction between lines L1 and L2 extending in the Y direction. The line L1 is a line segment circumscribing components forming the second circuit portion 422 from the part close to the first circuit portion 421 in plan view. Similarly, the line L2 a line segment circumscribing components forming the first circuit portion 421 from the part close to the second circuit portion 422 in plan view. Accordingly, the insulation region 424 is adjacent to both the first circuit portion 421 and the second circuit portion 422. The shape of the insulation region 424 in plan view is arbitrary and may be a shape other than a rectangle. That is, the lines L1 and L2 may have a crook or bend. In addition, although the insulation region 424 is formed across the entire length in the Y direction on the upper surface of the board body 410 in the example illustrated in FIG. 2, the insulation region 424 may be formed in a part of the entire length in the Y direction.

The pattern 426 is formed on an internal layer of the board body 410. The pattern 426 may be formed on any internal layer of the board body 410 and the number of internal layers which the patterns 426 are formed is also arbitrary. In the example illustrated in FIG. 2, the patterns 426 are formed on all internal layers of the board body 410. The patterns 426 are made of a thermal conductive material and formed by, for example solid patterns of copper.

The patterns 426 extend in the regions overlapping with the insulation region 424 in plan view. The patterns 426 may extend in the regions overlapping with the entire insulation region 424 in plan view or may extend in the regions overlapping with a part of the insulation region 424 in plan view in the X direction. Similarly, the patterns 426 may extend in the regions overlapping with the entire insulation region 424 in plan view or may extend in the regions overlapping with a part of the insulation region 424 in plan view in the Y direction. In the example illustrated in FIG. 2, the patterns 426 extend in the regions overlapping the entire insulation region 424 in the X direction in plan view. In addition, the cross sections of the patterns 426 illustrated in the lower part of FIG. 2 may be the same in the Y direction and, in this case, the patterns 426 extend in the regions overlapping the entire insulation region 424 in the Y direction in plan view. In this case, the patterns 426 are exposed to the outside of the board body 410 on the side surface in the Y direction of the board body 410.

The patterns 426 are thermally connected to the discharge resistor R1. In the example illustrated in FIG. 2, the patterns 426 are connected to the discharge resistor R1 via the through via 430. The through via 430 may be formed in some of the plurality of discharge resistors R1, may be formed for each of the discharge resistors R1, or may be formed between the discharge resistors R1 arranged in the Y direction. The through via 430 may be electrically insulated from the discharge resistors R1 or may be electrically connected to the discharge resistors R1. When the plurality of the through vias 430 are electrically connected to the corresponding discharge resistors R1, the discharge resistors R1 are connected in series via the plurality of the through vias 430 and the patterns 426.

As described above, the discharge resistors R1 are heat generating components and need to have a heat radiation structure. For this purpose, in the control board 400-1 for the inverter 4 illustrated in FIG. 2, the patterns 426 are made of a thermal conductive material and thermally connected to the discharge resistors R1, so the patterns 42 can function as heat radiation portions. In addition, since the patterns 426 extend in the regions overlapping with the insulation region 424 in plan view, the heat radiation function can be achieved in an aspect in which a restriction on the component mounting range is small. For example, in the example illustrated in FIG. 2, if the pattern 426 is formed on the lower surface of the board body 410, the component mounting range on the lower surface of the board body 410 is restricted. In contrast, since the control board 400-1 for the inverter 4 illustrated in FIG. 2 forms a heat radiation portion using an internal layer, the heat radiation function can be achieved in an aspect in which a restriction on the component mounting range on the surface (the lower surface in this example) of the board body 410 is small. In addition, since the region of an internal layer of the board body 410 overlapping with the insulation region 424 is a region (so-called dead space) not used for wiring, such a region can be efficiently used to achieve the heat radiation function.

In addition, particularly in the example illustrated in FIG. 2, since the patterns 426 are formed on all internal layer, the regions of internal layers of the board body 410 overlapping with the insulation region 424 can be fully used (the area can be maximized) to improve the heat radiation performance. In addition, since the insulation region 424 is formed adjacently to the first circuit portion 421 in the example illustrated in FIG. 2, the patterns 426 can extend to the regions overlapping with the insulation region 424 in plan view from the part close to the first circuit portion 421 without overlapping with circuit portions other than the first circuit portion 421 in plan view. This achieves the heat radiation function without eliminating the possibility of using an internal layer of the board body 410 for wiring with respect to a circuit portion other than the first circuit portion 421.

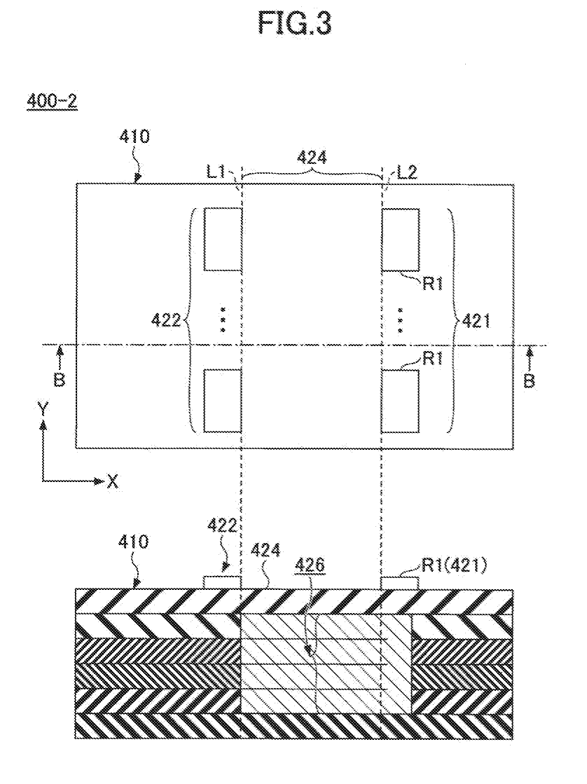

FIG. 3 schematically illustrates the control board 400-2 for the inverter 4 in the other example, the upper part of FIG. 3 illustrates plan view, and the lower part of FIG. 3 is a cross sectional view taken along line B-B in the upper part of FIG. 3.

The control board 400-2 is different from the control board 400-1 only in that the control board 400-2 does not have the through via 430. The other components that may be the same as in the above example are given the same reference numerals and descriptions are omitted.

The control board 400-2 for the inverter 4 illustrated in FIG. 3 also has the same effects as the control board 400-1 for the inverter 4. As described above, an aspect of thermal connection between the patterns 426 and the discharge resistors R1 is arbitrary, so the through via 430 does not need to be used.

Although embodiments have been described above, the invention is not limited to particular embodiments and various modifications and changes can be made within the scope designated. In addition, all or a plurality of components of the above embodiments may be combined.

For example, although the heat generating component is the discharge resistors R1 that need to be heat-radiated in the above embodiments, the heat generating component may be any component mounted on the control board 400-1 (control board 400-2). For example, the heat generating component may be a microcomputer chip.

In addition, although the insulation region 424 is formed adjacently to the first circuit portion 421 in the above embodiments, the insulation region 424 does not need to be adjacent to the first circuit portion 421. That is, another circuit portion may be formed between the insulation region 424 and the first circuit portion 421.

In addition, although the control board 400-1 (control board 400-2) is to be used for the inverter 4 in the above embodiments, the invention is not limited to the embodiments. For example, when a DC-DC converter (another example of the power conversion device) is provided between the smoothing capacitor C1 and the battery the control board 400-1 (control board 400-2) may be formed as a control board for the DC-DC converter instead of (or in addition to) a control board for the inverter 4.

In addition, although the pattern 426 is a solid pattern widely extending in both the X direction and the Y direction in the above embodiments, the pattern 426 may be a collection of a plurality of linear patterns extending in the X direction or the Y direction.

The following examples will be further disclosed with respect to the above embodiments.

(1)

The control board 400-1 or 400-2 for a power conversion device, including the board body 410 that is a multilayer board, the first circuit portion 421 including the heat generating component (R1) mounted on a first surface of the board body, the second circuit portion 422 mounted on the first surface of the board body 410, the second circuit portion 422 using a voltage different from a voltage of the first circuit portion 421, the insulation region 424 formed on the first surface of the board body 410, the insulation region 424 performing insulation between the first circuit portion 421 and the second circuit portion 422, and the pattern 426 of a thermal conductive material formed on an internal layer of the board body 410, extending in a region overlapping with the insulation region 424 as seen from the direction orthogonal to the first surface of the board body 410, and thermally connected to the heat generating component (R1).

In the structure described in (1), since the pattern 426 is made of a thermal conductive material and thermally connected to the heat generating component (R1), the pattern 426 can function as a heat radiation portion. In addition, since the pattern 426 extends in the region overlapping with the insulation region 424 as seen from the direction orthogonal to the first surface of the board body 410, the pattern 426 can be formed using a region (so-called dead space) not used for wiring in an internal layer of the board body 410. Accordingly, the heat radiation function can be achieved in an aspect in which a restriction on the component mounting range on the surface of the board body 410 is small.

(2)

The control board 400-1 or 400-2 for a power conversion device described in (1), in which the insulation region 424 is formed adjacently to the first circuit portion 421.

In the structure described in (2), since the insulation region 424 is formed adjacently to the first circuit portion 421 the pattern 426 can extend to the region overlapping with the insulation region 424 without overlapping with a circuit portion other than the first circuit portion 421 as seen from the direction orthogonal to the first surface of the board body 410. This achieves the heat radiation function without eliminating the possibility of using an internal layer of the board body 410 for wiring with respect to a circuit portion other than the first circuit portion 421.

(3)

The control board 400-1 or 400-2 for a power conversion device described in (1) or (2), in which the heat generating component (R1) is a discharge resistor,

In the structure described in (3), the discharge resistor having a large amount of heat generation can he efficiently heat-radiated by the pattern 426.

(4)

The control board for a power conversion device described in (3), in which the power conversion device is the inverter 4 provided in parallel to the smoothing capacitor C1, the discharge resistor R1 of the first circuit portion 421 has a function of discharging an electric charge of the smoothing capacitor C1, and the second circuit portion 422 includes a control circuit portion for controlling the inverter 4.

The present international application claims priority based on Japanese Patent Application No. 2014-156768 filed on Jul. 31, 2014, and the entire contents thereof are incorporated herein by reference.

1-4. (canceled)

5. A control board for a power conversion device, the control board comprising:
a board body that is a multilayer board;
a first circuit mounted on a first surface of the board body and including a heat generator;
a second circuit mounted on the first surface of the board body, the second circuit using a voltage different from a voltage of the first circuit;
an insulation region formed on the first surface of the board body, the insulation region performing insulation between the first circuit and the second circuit; and
a pattern of a thermal conductive material formed on an internal layer of the board body, extending in a region overlapping with the insulation region as seen from a direction orthogonal to the first surface of the board body, and thermally connected to the heat generator.

6. The control board for a power conversion device according to claim 5, wherein the insulation region is formed adjacently to the first circuit.

7. The control board for a power conversion device according to claim 5, wherein the heat generator is a discharge resistor.

8. The control board for a power conversion device according to claim 6, wherein the heat generator is a discharge resistor.

9. The control board for a power conversion device according to claim 7,
wherein the power conversion device is an inverter provided in parallel to a smoothing capacitor,
the discharge resistor of the first circuit has a function of discharging an electric charge of the smoothing capacitor, and
the second circuit includes a control circuit for controlling the inverter.

10. The control board for a power conversion device according to claim 8,
wherein the power conversion device is an inverter provided in parallel to a smoothing capacitor,
the discharge resistor of the first circuit has a function of discharging an electric charge of the smoothing capacitor, and
the second circuit includes a control circuit for controlling the inverter.
